(19) United States
(12) Patent Application Publication
(10) Pub. No.: US 2009/0091483 A1
(43) Pub. Date: Apr. 9, 2009

(54) FLASH ANALOG TO DIGITAL CONVERTER (ADC)

(75) Inventors: Jagannathan Venkataraman, Bangalore (IN); Abhaya Kumar, Bangalore (IN)

Correspondence Address: TEXAS INSTRUMENTS INCORPORATED, P O BOX 655474, M/S 3999, DALLAS, TX, 75265, US

(73) Assignee: TEXAS INSTRUMENTS INCORPORATED, Dallas, TX (US)

(21) Appl. No.: 11/867,014

(22) Filed: Oct. 4, 2007

(51) Int. Cl. H03M 1/00; H03M 1/44

(52) U.S. Cl. 341/141; 341/155; 341/172

(57) ABSTRACT

A flash ADC in which different thresholds are provided to different comparators in different time instances. Such a feature may be advantageously used in digital converters type components since the flash ADC would provide more time for amplifiers to generate amplified residue signals.

### BACKGROUND

1. Field of the Invention

The present invention relates generally to electronic circuits, and more specifically a flash analog to digital converter (ADC).

2. Related Art

Flash ADCs refer to structures/circuits which compare the strength (e.g., voltage) of an input signal against multiple threshold levels, and provide multiple output bits, with each output bit indicating a comparison result. Each output bit is generally of one binary value when the corresponding threshold level is less than the input voltage and of the other binary value otherwise. The output bits together represent a digital code corresponding to the strength of the input signal and can be encoded as a binary value, as is well known in the relevant arts.

Flash ADCs may need to be implemented with various architectures to meet the requirements of corresponding environments.

### BRIEF DESCRIPTION OF THE DRAWINGS

The present invention will be described with reference to the following accompanying drawings, which are described briefly below.

FIG. 1 is a block diagram of a pipeline ADC illustrating the details of an example environment in which several aspects of the present invention can be implemented.

FIG. 2 is a block diagram illustrating the logical operation of a stage of a pipeline ADC.

FIG. 3 is a block diagram illustrating a typical residue amplification stage in a pipeline ADC, also illustrating the need for the output bits of a flash ADC contained in the pipeline ADC to be provided on different output terminals for different samples, in an embodiment.

FIG. 4 is a block diagram illustrating the details of an example prior flash ADC.

FIG. 5 is a timing diagram illustrating some deficiencies caused by the design of the prior flash ADC.

FIG. 6 is a block diagram illustrating the details of a flash ADC according to an aspect of the present invention.

FIG. 7 is a timing diagram illustrating how deficiencies caused by the design of the prior flash ADC are overcome in an embodiment of the present invention.

FIG. 8 is a block diagram of a switching block in an embodiment of the present invention.

FIG. 9 is a block diagram illustrating the connections from a switching block to differential comparators in an embodiment of the present invention.

FIG. 10 is a block diagram illustrating an example device in which various aspects of the present invention can be implemented.

In the drawings, like reference numbers generally indicate identical, functionally similar, and/or structurally similar elements. The drawing in which an element first appears is indicated by the leftmost digit(s) in the corresponding reference number.

### DETAILED DESCRIPTION

### 1. Overview

A flash ADC in which different thresholds are provided to different comparators in different time instances. Such a feature may be advantageously used in digital converters type components (analog to digital converters and digital to analog converters) since the flash ADC would provide more time for amplifiers to generate amplified residue signals.

Several aspects of the invention are described below with reference to examples for illustration. It should be understood that numerous specific details, relationships, and methods are set forth to provide a full understanding of the invention. One skilled in the relevant art, however, will readily recognize that the invention can be practiced without one or more of the specific details, or with other methods, etc. In other instances, well known structures or operations are not shown in detail to avoid obscuring the features of the invention.

### 2. ADC

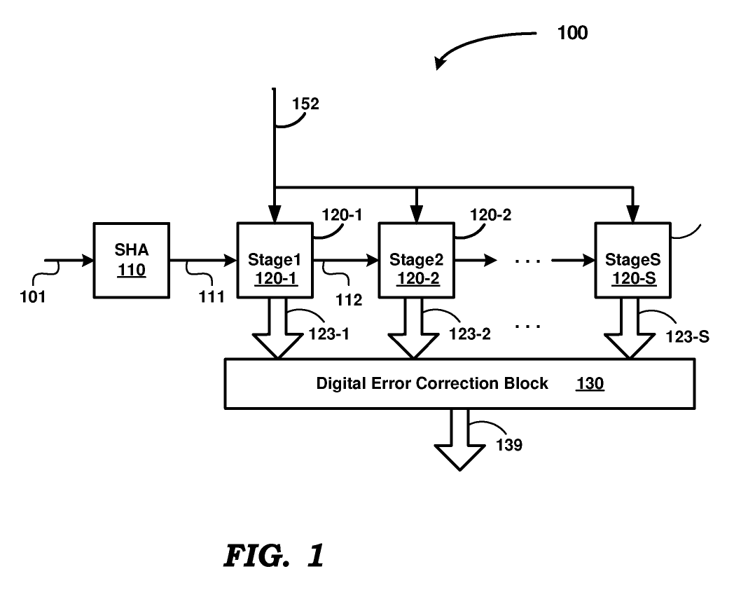

FIG. 1 is a block diagram of an ADC illustrating the details of an example environment in which several aspects of the present invention can be implemented. Pipeline ADC 100 is shown containing sample and hold amplifier (SHA) 110, stages 120-1 through 120-S, and digital error correction block 130. Each block is described below in further detail.

SHA 110 samples the input signal received on path 101 and holds the voltage level of the sample on path 111 for further processing.

Digital error correction block 130 receives sub-codes from various stages (on paths 123-1 through 123-S respectively), and generates a digital code representing a corresponding sample of the input signal received on path 101. Various error correction approaches, well known in the relevant arts, may be used to correct any errors in the received sub-codes. The generated digital code is provided on path 139 as a final digital code corresponding to the voltage of a sample on the input analog signal at a particular time instant.

Each stage 120-1 through 120-S generates a sub-code (based on a reference signal Vref received on path 152) corresponding to a voltage level of a signal received as an input, and an amplified residue signal as an input to a (any) next stage. For example, stage 120-1 converts a voltage level on path 111 to generate a sub-code on path 123-1, and the amplified residue signal generated on path 112 is provided as an input to stage 120-2. A common reference signal Vref is provided to stages 120-1 through 120-S.

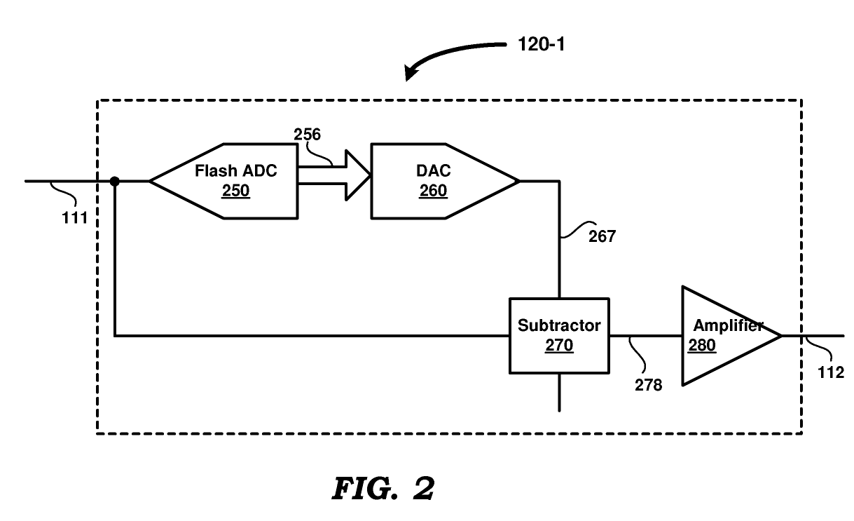

FIG. 2 further illustrates the logical operation of a stage (described with reference to stage 120-1 only, for conciseness) of a pipe line ADC according to a known approach.

With respect to FIG. 2, stage 120-1 is shown containing flash ADC 250, digital to analog converter (DAC) 260, subtractor 270 and amplifier 280. Flash ADC 250 (an example of a sub ADC) converts a sample of an analog signal received on path 111 into a corresponding P-bit sub-code provided on path 256 (contained in path 123-1 of FIG. 1, and P is less than N, where N is the number of bits in the final digital code provided on path 139 of FIG. 1).

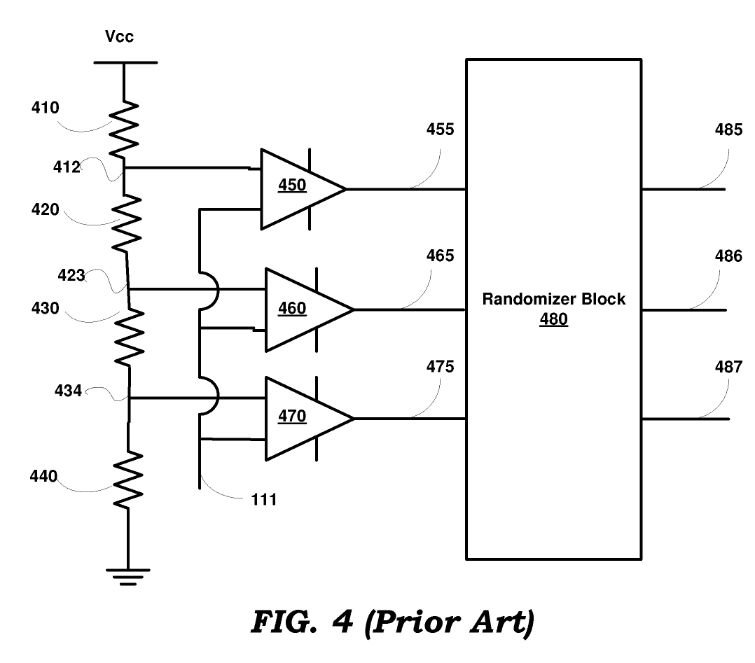

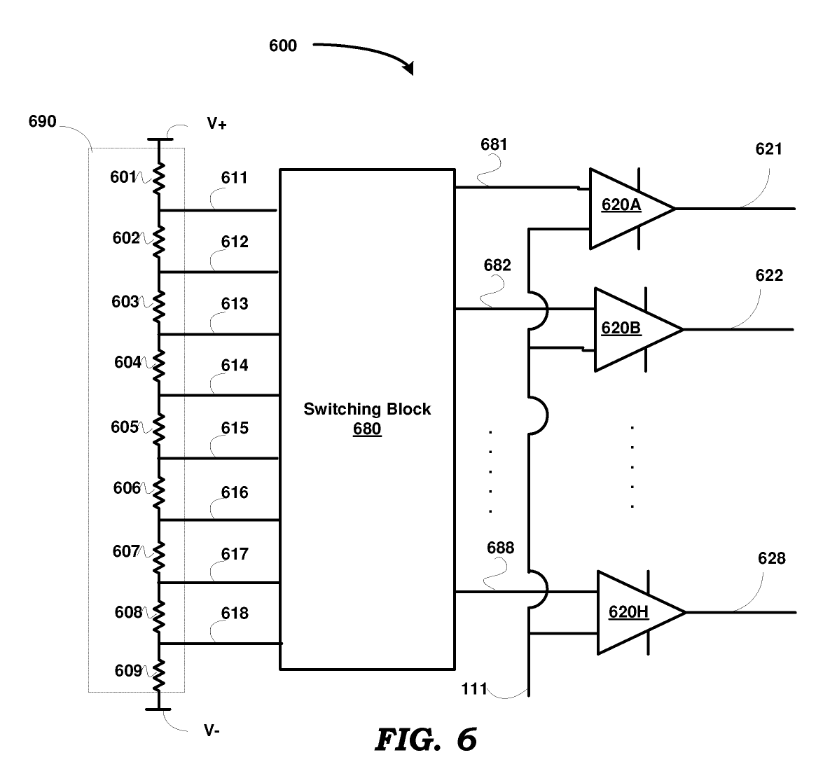

As relevant to understanding the example embodiments of the present invention described below, the P bit digital code is represented in the form of 2^{P} output bits, with the number of output bits of a binary value (e.g., 1) representing the P-bit sub-code, as also described in detail with respect to FIGS. 4 and 6 below

DAC 260 converts the sub-code received on path 256 into corresponding analog signal (Vdac) on path 267. Subtractor 270 generates a residue signal as the difference of sample 111 (Vi) and the analog signal received on path 267. Amplifier 280 amplifies the residue signal (Vi-Vdac) which is then provided on path 112 as an amplified residue signal. The signal on path 112 is used to resolve the remaining bits in the N-bit digital code by the subsequent stages of the ADC.

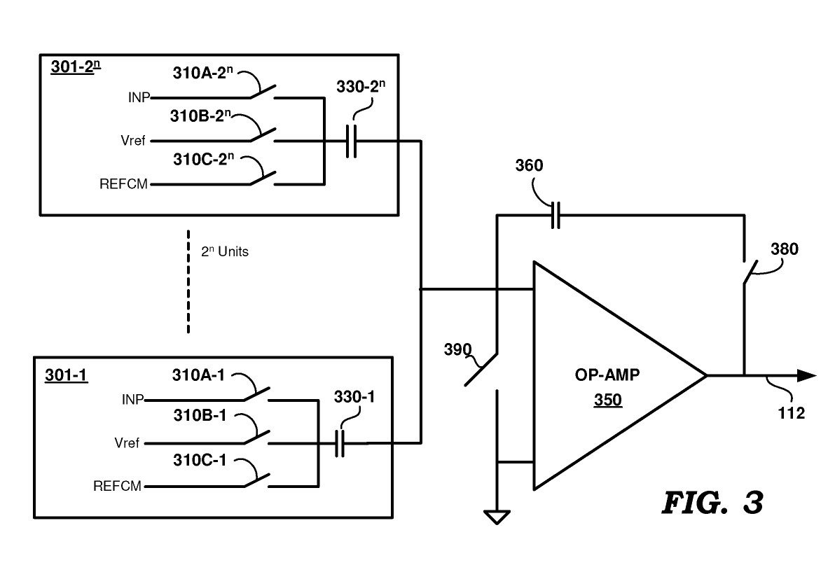

The manner in which the residue signal is generated by each stage is described below with respect to FIG. 3, which also illustrates the need for the individual output bits of a flash ADC to be provided on different output terminals for different samples.

### 3. Capacitor Mismatches

FIG. 3 is a circuit diagram illustrating the manner in which DAC 260, subtractor 270, and gain amplifier 280 are implemented in an embodiment. The circuit diagram is shown containing op-amp 350, feedback capacitor 360, feedback switch 380 and circuit portions 301-1 through 301-2n. The circuit is referred to as a gain (or residue amplification) block and operates to provide the function of components DAC 260, subtractor 270 and amplifier 280. FIG. 3 shows a gain stage in a single ended implementation, but equivalent embodiments can be implemented in differential form also.

Circuit portion 301-1 is shown containing sampling capacitor 330-1, switch 310A-1, 310B-1 and 310C-1. The remaining circuit portions 310-2 through 310-2ⁿ may also contain similar components, and are not shown/described in the interest of conciseness. The operation of each component is described below in further details.

During a first (e.g., sampling) phase (illustrated in greater detail below with respect to a timing diagram) switches 310A-1 through 310A-2ⁿ and switch 390 are closed, while switches 380, 310B-1 through 310B-2n, and 310C-1 through 310C-2n are kept open. As a result, each sampling (input) capacitor 330-1 through 330-2n is ideally charged to the voltage of input sample received on path 111.

During a next (e.g., hold) phase, feedback switch 380 is closed, and switches 310A-1 through 310A-2n as well as switch 390 are kept open. Connections of switches 310B-1 through 310B-2n, and 310C-1 through 310C-2n are made such that the input terminals of each sampling capacitors 330-1 through 330-2ⁿ is connected either to Vref or to REFCM terminal, based on the corresponding output bits of comparators used in flash ADC 250. In an embodiment, each switch pair (such as switch pair 310B-1/310C-1) is controlled by an output bit from a corresponding comparator used in flash ADC 250. (It is clarified here that flash ADC 250 may further process the output bits of the constituent comparators, for example in an encoding block, to provide the sub-codes as P-bit values on path 256).

As a result, capacitors 330-1 through 330-2n transfer a charge proportional to the difference (residue) of input signal and Vref or REFCM to feedback capacitor 360. The residue is amplified by op-amp 350 and provided as amplified residue signal to the next stage, as desired. However, mismatches (actual values being different from desired values) in the capacitance values of capacitors 330-1 through 330-2ⁿ may result in the residue signal (and hence the final digital code on path 139) to be in error. For example, in some implementations capacitors 330-1 through 330-2ⁿ may be selected to have equal capacitance values.

However, due to implementation (e.g., fabrication variations) inaccuracies, and other undesirable effects, the actual capacitance values may vary from the desired values, often resulting in the residue value (as well as the final digital codes) to have a non-linear relationship with respect to the input signal 101, which is undesirable. Such a non-linear relationship may cause spurious tones in the output spectrum of the pipeline ADC resulting in a degradation of the SFDR (spurious free dynamic range) of the pipeline ADC. Further, the extent of non-linearity may vary depending on the amplitude of the input signal 101, possibly causing the SFDR to change by different amounts for different input signal strengths.

Assuming that capacitance values (denoted Ci) of each of capacitors 330-1 through 330-2ⁿ is required ideally to equal the capacitance (denoted C(f)) of capacitor 360, but differs from C(f) by a corresponding value ΔCi, each of the capacitances may be expressed as:

Ci=C(f)+ΔCi,

wherein index i ranges from 1 to n corresponding to capacitors 330-1 through 330-2ⁿ.

Residue value on path 112 may be expressed by the following equation:

$$Vout = 1 + \frac{{\sum }_{1}^{2 ( B ) - 1} C ( i )}{C ( F )} \cdot Vin + \frac{{\sum }_{1}^{2 ( B ) - 1} d ( i ) \cdot C ( i )}{C ( F )} \cdot Vref \qquad Equation 1$$

wherein,

Vout is the residue signal on path 112,

C(F) is the capacitance of capacitor 360,

Vin is the voltage of input signal 111,

C(i) is the capacitance of the ith capacitor, where index i specifies capacitors 330-1 through 330-2n for corresponding index values,

d(i) is the binary output of the corresponding comparator of flash ADC 250.

B has a value of (N+1) where N is the number of bits of sub-code provided by flash ADC250.

Vout of equation 1 may be expressed as given below:

$$Vout = G \cdot ( 1 + \frac{Δ G}{G} ) \cdot ( Vin + ( \frac{{\sum }_{1}^{2 ( B ) - 1} d ( i ) \cdot C ( i )}{G \cdot C ( F )} \cdot Vref ) ) , \qquad Equation 2$$

wherein,

G is the ideal required gain, and equals 2̂B−1, wherein ̂ specifies a ‘power of’ operation, and

the term 2(B)−1 in equation 2 equals the value of the expression 2̂B−1.

Equation 2 may be re-arranged to provide:

$$Vout = G \cdot ( 1 + \frac{Δ G}{G} ) \cdot ( \begin{matrix}V ( i n ) + \frac{1}{G} \cdot ( {\sum }_{1}^{2 ( B ) - 1} d ( i ) ) \cdot \\ Vref + Δ Vref\end{matrix} ) \qquad Equation 3$$

ΔVref of equation 3 may be expressed as:

$$Δ Vref \approx \frac{1}{G} \cdot ( {\sum }_{1}^{2 ( B ) - 1} d ( i ) \cdot \frac{Δ C ( i )}{C ( F )} ) \cdot Vref . \\ wherein Δ C ( i ) = C ( i ) - C ( F ) . \qquad Equation 4$$

ΔVref is a measure of the error due to capacitor mismatch. It may be noted that in an ideal pipeline ADC having no non-linearity errors, the residue amplifier's output should change by a strength equal to the reference voltage provided to the next stage (120-2 in FIG. 1), i.e., Vref for a corresponding change of one step (one bit change (d(i)) in flash ADC 250). It may be observed from equation 3 that the term ΔVref may cause a deviation from the ideal change noted above, which results in non linearities (generally measured in terms of DNL (differential non linearities), INL (intergral non linearities) or SFDR (spurious free dynamic range) and THD (total harmonic distortions).

A prior technique attempts to overcome the problem noted by providing the individual output bits of a flash ADC on different output terminals for different samples (corresponding to different sampling instances) as described briefly below.

### 4. Prior Flash ADC

FIG. 4 is a block diagram of a prior implementation of Flash ADC 250 of FIG. 2. For simplicity, flash ADC 250 is shown as providing three output bits. Prior flash ADC is shown containing resistors 410, 420, 430 and 440, comparators 450, 460 and 470, and randomizer block 480. It may be noted that when circuit of FIG. 4 is used in conjunction with the circuit of FIG. 3, three sampling capacitors 330-1, 330-2 and 330-3 (FIG. 3) are used.

Comparators 450, 460 and 470 provide respectively on paths 455, 465 and 475 a result of a comparison of input signal 111 against respective threshold voltages at nodes 412, 423 and 434.

Randomizer block 480 provides (routes) comparator outputs 455/465/475 on a different one of output paths 485, 486 or 487 in each sampling instance. Thus, for example, randomizer block 480 may provide output 455 on path 485, output 465 on path 486, and output 475 on path 487 corresponding to a first sampling instance, but provide output 455 on path 487, output 465 on path 485, and output 475 on path 486 corresponding to a subsequent sampling instance.

The routing (path mapping) from the comparator outputs 455/465/475 to outputs 485/486/487 may be done in a random manner. Thus, each of switch pairs (such as switch pair 310B-1/310C-1 of FIG. 3), and thus the corresponding one of capacitors 330-1 through 330-2ⁿ may be controlled by a different one of comparator outputs 455/465/475, at different time instances.

Since the comparator outputs 455/465/475 of Flash ADC 250 control which of voltages Vref or REFCM is connected to respective capacitors 330-1 through 330-2ⁿ, the prior technique, in providing the individual comparator output bits of a flash ADC on different output terminals for different samples, spreads the errors due to capacitor mismatch over the entire nyquist bandwidth, thereby reducing the degradation in SFDR noted above. This is typically referred to as ‘dynamic element matching’ technique where a different one of capacitors 330-1 through 330-2n is connected to a same flash output bit at different time instances by the randomizer block.

Thus, ΔVref error will be different at different time instances because of different capacitors from the set 330-1 through 330-2n being chosen for the same output bit line of flash ADC 250. Thus the error pattern is randomized and it breaks the repetitive pattern that is the cause of SFDR and spreads this energy over the entire nyquist bandwidth.

However, the prior technique of FIG. 4 described above has a drawback in that the routing operation of randomizer block 480 is in a critical path of the signal chain. The technique therefore introduces an additional delay which reduces the amount of time available to the following DAC-subtractor-amplifier circuit (FIG. 3), as is described next with respect to a timing diagram.

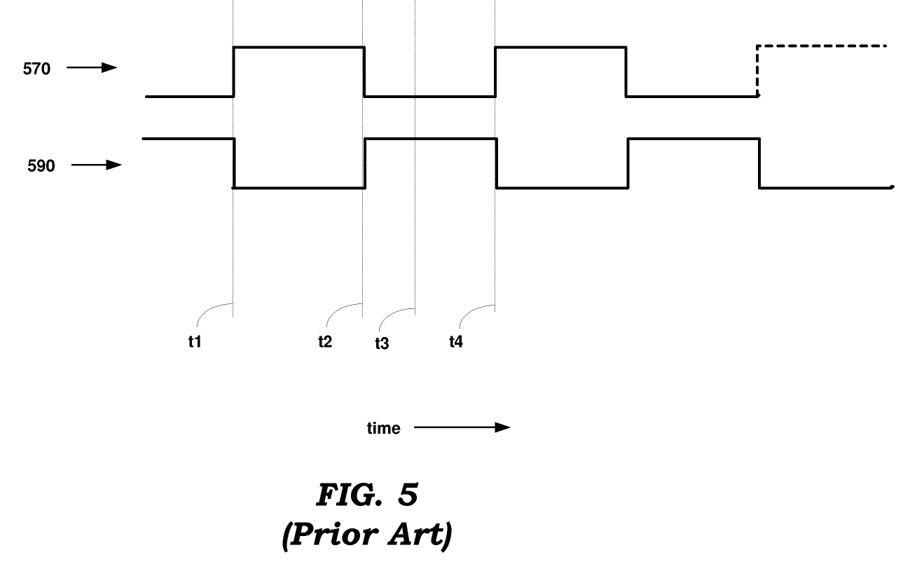

FIG. 5 is a timing diagram illustrating a reduced time available to the circuit of FIG. 3 when the prior technique noted above is used. FIG. 5 shows two phase signals sample phase 570 and hold phase 590.

At time instance t1, internal capacitors (not shown) in comparators 450, 460 and 470 of flash ADC 250 complete charging to a corresponding threshold voltage (one of thresholds at nodes 412, 423 or 434), and begin sampling input signal 111. Also at time instance t1, switches 310A-1 through 310-3 are closed and charge to input signal voltage the corresponding capacitors 330-1 through 330-3, as noted above.

At time instance t2, outputs 455, 465 and 475 contain the comparison result performed by respective comparators 450, 460 and 470. Also (ideally) at time instance t2, capacitors 330-1 through 330-2ⁿ are ready to be connected to either Vref or REFCM depending on the output bits 485-487 of flash 250.

However, randomizer block 480 may take an additional amount of time (t3−t2) to provide valid output bits on paths 485-487 at time instance t3. This additional time may increase if the number of bits in the flash ADC is more because of multiple levels of logic required to be implemented in randomizer block 480.

Once the outputs on path 485-487 are valid at t3, capacitors 330-1 through 330-2ⁿ may be connected to either Vref or REFCM (depending on the value of the corresponding bits), and the circuit of FIG. 3 operates to provide a corresponding residue signal on path 112 at time instance t4.

It may be appreciated, that the introduction of randomizer block 480 creates a delay in a critical path of the pipeline ADC viz., the residue amplification stage. Ideally it may be desirable to provide the entire duration from time instance t2 to t4 for OPAMP 350 to generate the residue signal. However, as may be apparent from FIG. 5, OPAMP 350 when operated according to the prior technique has a lesser duration of time to generate the residue signal.

At least when operating in high speed environments (where the duration to generate the residue signal is correspondingly short), OPAMP 350 may need to be designed as a high power component, which would consume proportionately more current/power.

Thus, the prior technique noted above may not be suitable at least for high speed ADC operation. Various aspects of the present invention provide for an improved flash ADC, as described below in further detail.

### 5. Improved Flash ADC

FIG. 6 is a block diagram of a flash ADC in an embodiment of the present invention. Flash ADC 600 is shown containing comparators 620A-620H, switching block 680, and threshold block 690. Each block is described below in detail.

Threshold block 690 generates threshold signals to be used for comparison against an input signal, and is shown implemented as a resistor ladder containing resistors 601-609. The resistor ladder operates as a voltage divider (to derive voltages from reference voltages V+ and V−), and provides threshold voltage levels on corresponding paths 681-688.

Thus, in the Figure, assuming resistors 601-609 are all of equal resistance values, and assuming that the V− terminal is connected to ground, path 611 provides a threshold voltage of ⅞V+, path 612 provides a threshold voltage of 6/8V+, path 613 provides a threshold voltage of ⅝V+ etc. Although shown implemented as a resistor ladder, threshold block 690 may be designed using other techniques to generate the voltage thresholds. When sampling the strength of current, corresponding alternative structures, well known in the relevant arts, can be used to provide the current thresholds.

Each of comparators 620A-620H receives a threshold voltage on respective input terminals 681-688, and input signal 111 on a second input terminal, and provides on respective paths 621-628 a result (output bit) of the comparison of the threshold voltage and input signal 111. The result may equal logic one in case the input signal is greater than the respective threshold voltage and logic zero otherwise. The output bits may be latched by corresponding memory elements, not shown.

When used in conjunction with flash ADC 600 the circuit of FIG. 3 may contain eight sampling capacitors 330-1 through 330-8, corresponding to circuit blocks 301-1 through 301-8. Referring to FIG. 3, output bits on respective paths 621-628 control a corresponding switch pair to connect the sampling capacitors to Vref or REFCM, with the connection being fixed.

Thus, for example, path 621 may be permanently connected (hard-wired) to control switch pair 310B-1/310C-1, while path 628 may be permanently connected (hard-wired) to control switch pair 310B-8/310C-8.

Merely for illustration, only eight comparators are shown in FIG. 6, but more/less comparators may be included as suitable for particular scenario. In general, the number of comparators may equal 2^{P}, wherein P represents the number of bits in the binary representation of the subcode.

It may be noted that, in contrast, in the prior technique described above, capacitors 330-1 through 330-3 and the corresponding switch pair may be controlled by a different one of comparator outputs 455/465/475 at different time instances. The outputs of comparators 620A-620H together represent (e.g., proportional to the number of outputs with a logical value of 1) a strength of input signal 111.

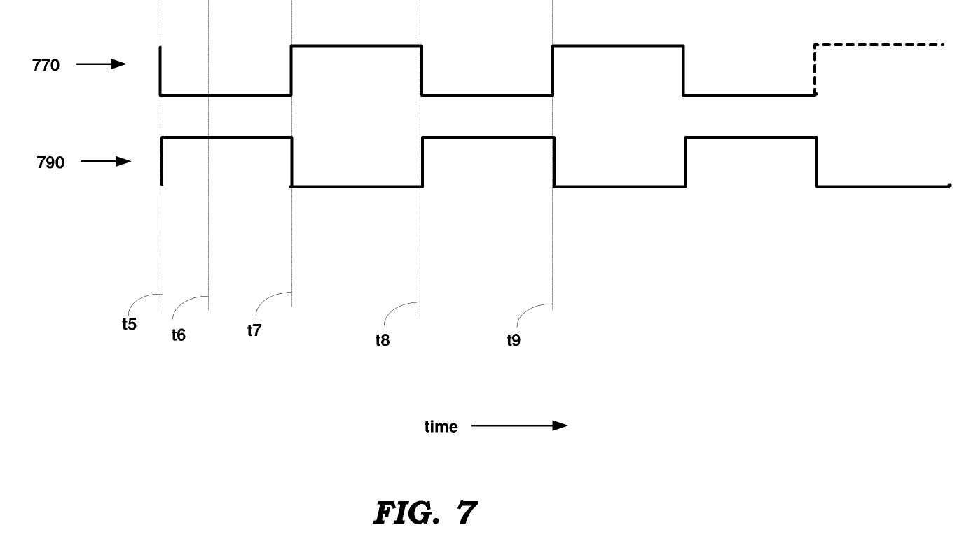

Switching block 680 receives threshold voltages on paths 611-618 and operates to route the threshold voltages to a different one of paths 681-688 at different time instances. Thus, as an example, switching block 680 may connect path 611 to path 682 at a first time instance (for example, corresponding to threshold voltage sampling phase corresponding to time period t6-t7, described below with respect to FIG. 7), but connect path 611 to path 683 at a subsequent time instance.

It may be appreciated that since comparators 620A-620H receive different threshold voltages at different time instances, different (a different set of) capacitors may be used for a same set of comparator output bits at different times. As a result, capacitor mismatch errors are spread to wide band noise and the SFDR performance of the ADC is improved.

Further, it may be noted that since switching block 680 is not in a critical path of the signal chain, more time is available to the circuit of FIG. 3 to generate a residue signal, as described next with respect to FIG. 7.

FIG. 7 shows two phase signals, viz., sample phase 770 and hold phase 790 used to control various internal operations of a pipeline ADC containing a stage built using flash ADC 600 and the gain block of FIG. 3. Phase (clock) signals 770 and 790 may be provided to operate corresponding switches internal to flash ADC 600 and gain block of FIG. 3 during corresponding sample and hold phases.

At time instance t5, switching block 680 initiates a switching operation to route paths 611-618 to a corresponding one of paths 681-688. At time instance t6, switching block 680 completes the switching operation.

At time instance t6, internal capacitors (not shown) in comparators 620A-620H of flash ADC 600 begin charging to the corresponding threshold voltage (available on paths 681-688 at the end of the operation of switching block 680 at time instance t6). The comparators complete charging to the threshold voltage at time instance t7. At time instance t7, comparators 620A-620H begin sampling input signal 111.

Also at time instance t7, switches 310A-1 through 310A-3 (FIG. 3) are closed, and charge to input signal voltage 111 the corresponding capacitors 330-1 through 330-8.

At time instance t8, outputs bits 621-628 respectively contain the comparison result (output bits) provided by respective comparators 620A-620H.

Also at time instance t8, each of capacitors 330-1 through 330-8 may be connected to either Vref or REFCM depending on the value of the corresponding output bit 621-628 of flash ADC 600, and a corresponding residue signal on path 112 may be provided by time instance t8.

It may be observed that, the gain block (specifically OPAMP 350) of FIG. 3 now has more time to provide the residue signal. Assuming that the phase clocks of FIGS. 5 and 7 have the same frequency, OPAMP 350 has an available time (t9−t8) as against a shorter time (t4−t3) in the prior technique illustrated with respect to FIG. 5. As a result, OPAMP 350 may be implemented as a relatively lower power OPAMP and consumes lesser power when compared to the prior technique described above with respect to FIGS. 4 and 5.

A further advantage of the technique used in flash ADC 600 is that non-linearity effects due to offsets errors (if present) in comparators 620A-620H are also reduced, due to different thresholds being provided to the comparators at different time instances. Due to comparator offsets, the residue amplifier voltage output deviates from the ideal value and this can cause errors because of limited range for the active transistors used in the residue amplifier. Different comparators may have different offsets (due to process variations), and this may cause a specific error pattern that results in poor SFDR.

Also, the technique can be extended to measure the capacitor mismatches and used for digital calibration of the mismatches By individually controlling the operation of switching block 680, a specific one of capacitors from 330-1 to 330-2n can be connected to vref or REFCM. Thus, the ΔVref error corresponding to each capacitor can be measured and stored for digital calibration.

Merely for conciseness, only a single cycle of the sample and hold operations are shown in FIG. 7 and described. However, the cycle would be repeated multiple times. In each of the cycles, in duration t5-t6, switching block 680 may determine (and cause corresponding connections), with each of paths 611-618 being coupled to a potentially different one of paths 681-688 in different cycle instances.

Thus, in one clock cycle, path 611 may be coupled to path 681 and in the next clock cycle path 611 may be coupled to path 684. The couplings for remaining paths 612-618 is described similarly, with each (input) path being connected to different output path (681-688) in different clock cycles by time instance t6.

Switching block 680 may be implemented using any of several techniques, one of which is described next.

### 6. Switching Block

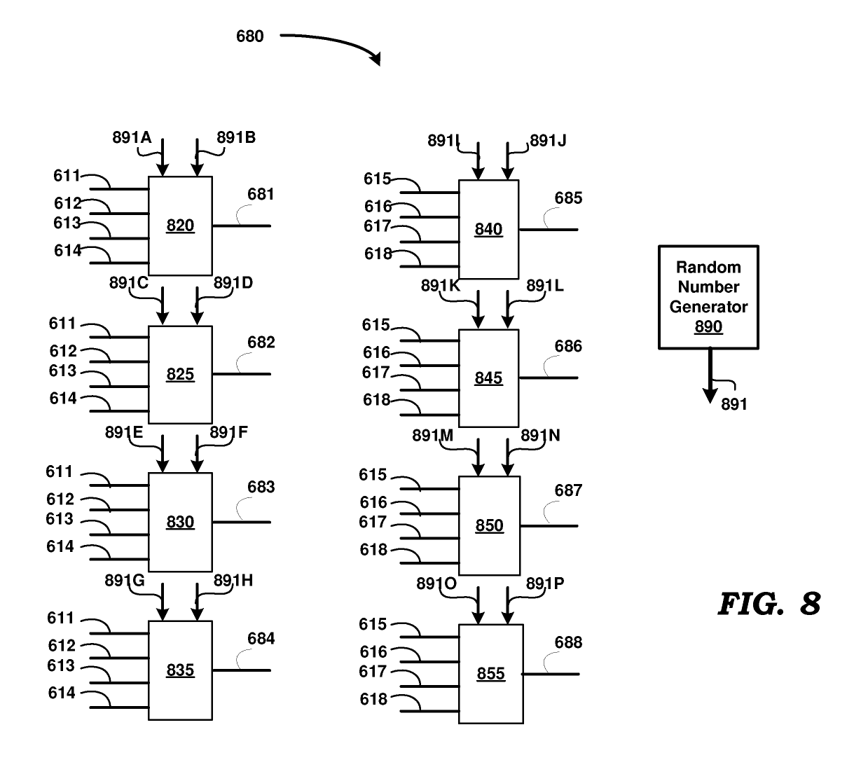

FIG. 8 is a block diagram of a switching block in an embodiment of the present invention implemented in differential form. In the Figure it is assumed that switching block 680 provides switching/routing for eight comparators operating with differential signals. Switching block 680 is shown containing analog multiplexers 820, 825, 830, 835, 840, 845, 850, and 855, and random number generator 890.

It is assumed that threshold voltages on paths 611-618 contain voltages of both polarities (V+ terminal and V− terminal of FIG. 6 being connected to positive and negative voltages respectively). In one example implementation, assuming that resistors 601-609 all have equal resistance values (except resistor 605, which may be equal to twice the other resistance values), threshold voltage levels of VCM+7V/16, VCM+5V/16, VCM+3V/16, VCM+V/16, VCM−V/16, VCM−3V/16, VCM−5V/16, and VCM−7V/16 are provided on paths 611-618 respectively, wherein V equals the magnitude of voltages at terminals V+ and V−, and VCM equals ((sum of V+ and V−)/2), VCM thus being the common mode of the two reference voltages.

Each of analog multiplexers 820, 825, 830 and 835 respectively connects respective paths 681-684 to one of input paths 611-614 based on the value of the corresponding select bits 891A-891H (forming select data). Each of analog multiplexers 840, 845, 850 and 855 respectively connects respective paths 685-688 to one of input paths 615-618 based on the value of the corresponding select bits 891I-891P (forming select data).

Random number generator 890 may be designed to generate random numbers, and provides select bits 891A-891P (contained in path 891) derived from the random number generated. The random numbers determine the coupling of each of the paths 611-618 to corresponding output paths 681-688. Although separate select bits 891A-891P are shown in the Figure, fewer select bits may be used in other embodiments.

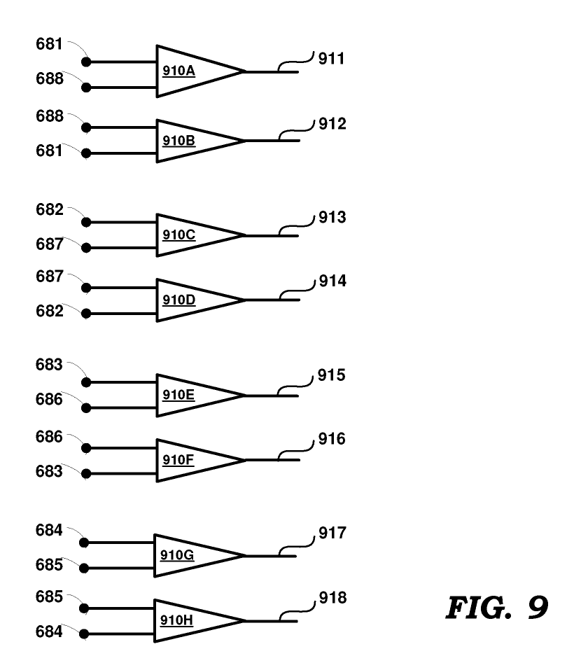

FIG. 9 shows differential comparators 910A-910H (used in place of single-ended comparators 620A-620H of FIG. 6) connected to the outputs of analog multiplexers as shown. The operation of the analog multiplexers provides a different threshold to each comparator at different time instances. Each of comparators 910A-910H also receives input signal 111 in a differential form on corresponding two input terminals of the comparator, but not shown in FIG. 9.

Thus, each comparator compares the input signal (received in differential form) with the corresponding differential threshold voltage, and generates the comparison result as an output bit provided on respective paths 911-918 (which can also be differential, though shown as a single line). It may also be appreciated that by reversing (flipping) the inputs to comparator pairs (for example, comparator 910A has its positive input terminal connected to path 681, and negative input terminal to path 688, while the inputs to comparator 910B is reversed), each analog multiplexer needs to select only one of four inputs (as against eight which may be required in a single-ended implementation).

Output bits 911-918 contain corresponding comparison results of the input signal 111 and corresponding thresholds, and may be provided to control corresponding switches and capacitors in a gain stage as described above with respect to FIG. 3.

It should be appreciated that a different one of select data is provided to each of the analog multiplexers, and the specific select data provided to each of the multiplexers is not the same in all cycles. For example, in one clock cycle, the select data provided to multiplexers 820, 825, 830, 835, 840, 845, 850 and 855 may respectively equal 0, 2, 3, 1, 3, 1, 0, and 2, while in the next clock cycle respective values of 3, 2, 1, 0, 0, 1, 2 and 3 may be provided due to the operation of random number generator 890.

When values of 0, 2, 3, 1, 2, 0, 1, and 3 are provided, voltages on paths 681-688 respectively carry voltages of (VCM+7V/16), (VCM+3V/16), (VCM+1V/16), (VCM+5V/16), (VCM−5V/16), (VCM−1V/16), (VCM−3V/16), and (VCM−7V/16) are received. Thus the differential threshold voltage applied to comparator 910A equals ((VCM+7V/16)−(VCM−7V/16)). Accordingly, comparator 910A compares the input signal 111 with voltage 7V/8.

The differential threshold voltages applied to comparators 910B-910H respectively equal −7V/8, 3V/8, −3V/8, 1V/8, −1V/8, 5V/8 and −5V/8. The specific threshold voltages can similarly be determined for other combinations of select data.

An ADC containing flash ADC 600 internally may be incorporated in a device/system, as described next.

### 7. System/Device

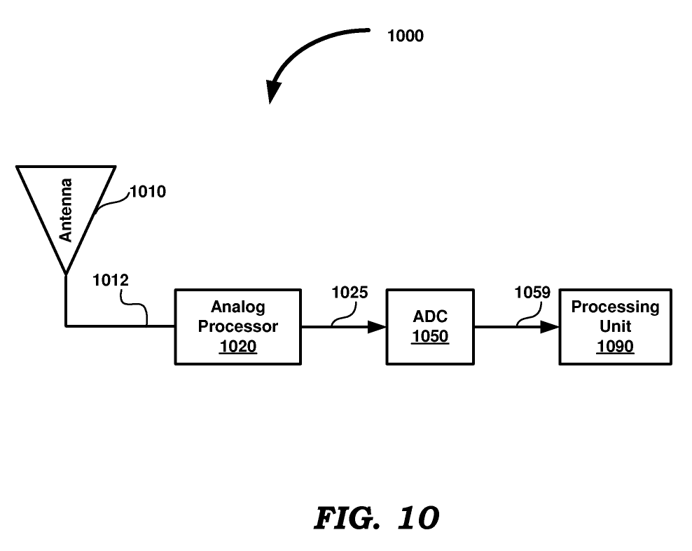

FIG. 10 is a block diagram of receiver system 1000 illustrating an example system in which the present invention may be implemented. Receiver system 1000, which may correspond to, for example, a mobile phone is shown containing antenna 1010, analog processor 1020, ADC 1050, and processing unit 1090. Each component is described in further detail below.

Antenna 1010 may receive various signals transmitted over a wireless medium. The received signals may be provided to analog processor 1020 on path 1012 for further processing. Analog processor 1020 may perform tasks such as amplification (or attenuation as desired), filtering, frequency conversion, etc., on received signals and provides the resulting signal on path 1025. The resulting signal is provided at a lower (e.g., baseband) frequency compared to the signal received from antenna 1010.

ADC 1050 converts the analog signal received on path 1025 to corresponding digital codes. ADC 1050 may contain a flash ADC implemented in a manner described above. ADC 1050 provides the digital codes to processing unit 1090 on path 1059 for further processing. Processing unit 1090 receives the recovered data to provide various user applications (such as telephone calls, data applications).

### 8. Conclusion

While various embodiments of the present invention have been described above, it should be understood that they have been presented by way of example only, and not limitation. Thus, the breadth and scope of the present invention should not be limited by any of the above-described embodiments, but should be defined only in accordance with the following claims and their equivalents.

What is claimed is:

1. A flash analog to digital converter (ADC) to generate digital codes representing a strength of an input signal at a sequence of time instances, said flash ADC comprising:
a threshold block to generate a plurality of thresholds, wherein each of said thresholds represents a different strength in a strength range of interest;
a plurality of comparators including a first comparator, wherein each of said plurality of comparators compares said strength of said sample with a corresponding one of said plurality of thresholds received on a corresponding input terminal;
a switching block providing a first threshold on the input terminal of said first comparator when said comparator compares the strength of said input signal at a first time instance and a second threshold on the input terminal of said first comparator when said comparator compares the strength of said input terminal at a second time instance,
wherein said first threshold and said second threshold are contained in said plurality of thresholds and said first threshold is not equal to said second threshold,
wherein the results of comparison of said plurality of comparators together represent the strength of said input signal at the corresponding time instances.

2. The flash ADC of claim 1, wherein said strength represents a voltage level, wherein said threshold block comprises a resistor ladder containing a plurality of resistors in series.

3. The flash ADC of claim 2, wherein said switching block comprises a plurality of multiplexers, wherein each of said multiplexor selects one of said plurality of thresholds based on a corresponding one of a plurality of selection values, wherein said selection values are provided to cause a first multiplexor to select said first threshold in said first time instance and to select said second threshold in said second time instance,
wherein the output of said first multiplexor is connected to the input terminal of said first comparator, and
wherein said first multiplexor is contained in said plurality of multiplexors.

4. The flash ADC of claim 3, wherein said input signal is received in a differential form, wherein said resistor network is connected between a positive reference voltage and a negative reference voltage, wherein each comparator is designed to receive the outputs of a pair of multiplexors, wherein the outputs of the pair of multiplexors represent a corresponding threshold.

5. The flash ADC of claim 3, further comprising a random number generator which determines which of said plurality of selection values is provided to which of the multiplexors in each time instance.

6. The flash ADC of claim 3, wherein said input signal is received in a singled ended form.

7. A stage of an ADC to generate digital codes representing a strength of an input signal at a sequence of time instances, said stage comprising:
a flash analog to digital converter (ADC) generating a plurality of binary values on a plurality of output terminals, said flash ADC comprising:
a threshold block generating a plurality of thresholds, wherein each of said thresholds represents a different strength in a strength range of interest;
a plurality of comparators including a first comparator, wherein each of said plurality of comparators compares said strength of said sample with a corresponding one of said plurality of thresholds received on a corresponding input terminal and provides a comparison result as a binary value on a corresponding one of said plurality of output terminals;
a switching block providing a first threshold on the input terminal of said first comparator when said comparator compares the strength of said input signal at a first time instance and a second threshold on the input terminal of said first comparator when said comparator compares the strength of said input terminal at a second time instance,
wherein said first threshold and said second threshold are contained in said plurality of thresholds and said first threshold is not equal to said second threshold,
wherein the results of comparison of said plurality of comparators together represent the strength of said input signal at the corresponding time instances,
a switched capacitor network and an amplifier together generating an amplified residue signal, wherein said amplified residue signal represents a residue signal amplified by a gain factor, wherein said residue signal represents a difference of the strength of said input signal at a corresponding time instance and a strength represented by said plurality of binary values for the corresponding time instance,
said switched capacitor network containing a plurality of capacitors, wherein each capacitor is charged by said input signal during a sampling phase and is connected to one of a pair of reference voltages if a result of the corresponding comparator is at a first logic value and to the other one of said pair of reference voltage if the result is at a second logic value during a hold phase.

8. The stage of claim 7, wherein said strength represents a voltage level, wherein said threshold block comprises a resistor ladder containing a plurality of resistors in series.

9. The stage of claim 8, wherein said switching block comprises a plurality of multiplexers, wherein each of said multiplexor selects one of said plurality of thresholds based on a corresponding one of a plurality of selection values, wherein said selection values are provided to cause a first multiplexor to select said first threshold in said first time instance and to select said second threshold in said second time instance,
wherein the output of said first multiplexor is connected to the input terminal of said first comparator, and
wherein said first multiplexor is contained in said plurality of multiplexors.

10. The stage of claim 9, wherein said input signal is received in a differential form, wherein said resistor network is connected between a positive reference voltage and a negative reference voltage, wherein each comparator is designed to receive the outputs of a pair of multiplexors, wherein the outputs of the pair of multiplexors represent a corresponding threshold.

11. The stage of claim 9, further comprising a random number generator which determines which of said plurality of selection values is provided to which of the multiplexors in each time instance.

12. The stage of claim 9, wherein said input signal is received in a singled ended form.

13. A device comprising:
a processing unit to process a plurality of digital codes; and
an analog to digital converter (ADC) to generate said plurality of digital codes respectively representing a strength of an input signal at a sequence of time instances, a stage of said ADC comprising:
a flash analog to digital converter (ADC) generating a plurality of binary values on a plurality of output terminals, said flash ADC comprising:
a threshold block generating a plurality of thresholds, wherein each of said thresholds represents a different strength in a strength range of interest;
a plurality of comparators including a first comparator, wherein each of said plurality of comparators compares said strength of said sample with a corresponding one of said plurality of thresholds received on a corresponding input terminal and provides a comparison result as a binary value on a corresponding one of said plurality of output terminals;
a switching block providing a first threshold on the input terminal of said first comparator when said comparator compares the strength of said input signal at a first time instance and a second threshold on the input terminal of said first comparator when said comparator compares the strength of said input terminal at a second time instance,
wherein said first threshold and said second threshold are contained in said plurality of thresholds and said first threshold is not equal to said second threshold,
wherein the results of comparison of said plurality of comparators together represent the strength of said input signal at the corresponding time instances,
a switched capacitor network and an amplifier together generating an amplified residue signal, wherein said amplified residue signal represents a residue signal amplified by a gain factor, wherein said residue signal represents a difference of the strength of said input signal at a corresponding time instance and a strength represented by said plurality of binary values for the corresponding time instance,
said switched capacitor network containing a plurality of capacitors, wherein each capacitor is charged by said input signal during a sampling phase and is connected to one of a pair of reference voltages if a result of the corresponding comparator is at a first logic value and to the other one of said pair of reference voltage if the result is at a second logic value during a hold phase.

14. The device of claim 13, wherein said strength represents a voltage level, wherein said threshold block comprises a resistor ladder containing a plurality of resistors in series.

15. The device of claim 14, wherein said switching block comprises a plurality of multiplexers, wherein each of said multiplexor selects one of said plurality of thresholds based on a corresponding one of a plurality of selection values, wherein said selection values are provided to cause a first multiplexor to select said first threshold in said first time instance and to select said second threshold in said second time instance,
wherein the output of said first multiplexor is connected to the input terminal of said first comparator, and
wherein said first multiplexor is contained in said plurality of multiplexors.

16. The device of claim 15, wherein said input signal is received in a differential form, wherein said resistor network is connected between a positive reference voltage and a negative reference voltage, wherein each comparator is designed to receive the outputs of a pair of multiplexors, wherein the outputs of the pair of multiplexors represent a corresponding threshold.

17. The device of claim 15, further comprising a random number generator which determines which of said plurality of selection values is provided to which of the multiplexors in each time instance.

18. The device of claim 15, wherein said input signal is received in a singled ended form.

19. The device of claim 13, further comprising:
an antenna to receive an external signal from a wireless medium; and
an analog processor to generate said input signal from said external signal, wherein said input signal is at a lower frequency compared to said external signal.
